(19) United States
(12) Patent Application Publication
(10) Pub. No.: US 2015/0090181 A1
(43) Pub. Date: Apr. 2, 2015

(54) AUTOMATED HEAT EXCHANGER ALIGNMENT

(71) Applicant: GT Crystal Systems, LLC

(72) Inventors: John Brouillette, Hudson, NH (US); Robert B. Farmer, Merrimack, NH (US); Kay Parpart, Gloucester, MA (US); Timothy R. Schuyler, Merrimack, NH (US)

(21) Appl. No.: 14/488,508

(22) Filed: Sep. 17, 2014

Related U.S. Application Data
(60) Provisional application No. 61/884,572, filed on Sep. 30, 2013.

(51) Int. Cl. C30B 11/00

(52) U.S. Cl. CPC C30B 11/007
USPC 117/223; 414/804

(57) ABSTRACT

According to the disclosed embodiments, a repeatable interface in a crystalline material growth system is achieved through an automated heat exchanger alignment apparatus and method. In one embodiment, a furnace chamber including a bottom wall and side walls that define an interior portion is provided. A crucible is disposed in the interior portion of the furnace chamber and configured to contain a crystalline material growth process. Also, a heat exchanger includes an elongated shaft that extends in a vertical direction and traverses the bottom wall of the furnace chamber, whereby a first end portion of the heat exchanger shaft is coupled to the crucible. Furthermore, an automated lifting device is configured to be actuated to adjust a position of the heat exchanger shaft in the vertical direction, whereby a second end portion of the heat exchanger shaft is coupled to the automated lifting device.

### CROSS-REFERENCE TO RELATED APPLICATION

The present application claims the benefit of U.S. Patent Application No. 61/884,572 filed Sep. 30, 2013, which is incorporated herein by reference.

### TECHNICAL FIELD

The present disclosure relates generally to crystalline material growth systems, and, more particularly, to an automated apparatus and method for aligning a heat exchanger.

### BACKGROUND

Several processes currently exist for the production of crystalline materials, such as silicon or sapphire. In certain processes, such as the heat exchanger method (HEM), the Czochralski (CZ) method, and directional solidification systems (DSS), crystallization furnaces are utilized for performing the melting and controlled resolidification of a feedstock material, e.g., silicon, aluminum oxide, or the like. Typically, a crucible containing the feedstock material is placed into the furnace and heated in order to fully melt the feedstock. The melted feedstock is then allowed to cool and solidify under controlled conditions, often using a heat exchanger, to initiate growth and crystallization of the feedstock material. This produces a solid feedstock in the crucible, sometimes referred to as an ingot or boule. The resulting crystalline ingot may later be processed for producing wafers to be used in a variety of high-end applications, such as in the semiconductor and photovoltaic industries.

A challenge for these crystallization growth processes is to ensure that a repeatable operational interface is achieved, such that a high level of system efficiency, stability, and predictability can be maintained. In order to achieve a repeatable interface, a force between the crucible and the heat exchanger must be constant for every crystal growth process on a particular machine. Problematically, variable factors affecting the load at the crucible, e.g., inconsistent feedstock amounts, crucibles of differing weights, etc., can make achieving a constant force between the crucible and the heat exchanger a difficult task. In other words, the downward force on the heat exchanger caused by the crucible may change from run-to-run, thereby hindering a repeatable operational interface. This problem can be further exacerbated when a new heat exchanger replaces an old one, which may generate a different counterforce against the crucible. As such, there is an increasing need in the industry for reliably achieving a consistent, repeatable interface in a crystallization growth system.

### SUMMARY

According to the disclosed embodiments, a repeatable interface in a crystalline material growth system is achieved through an automated heat exchanger alignment apparatus and method. In one embodiment, a furnace chamber including a bottom wall and side walls that define an interior portion is provided. A crucible is disposed in the interior portion of the furnace chamber and configured to contain a crystalline material growth process. Also, a heat exchanger includes an elongated shaft that extends in a vertical direction and traverses the bottom wall of the furnace chamber, whereby a first end portion of the heat exchanger shaft is coupled to the crucible. Furthermore, an automated lifting device is configured to be actuated to adjust a position of the heat exchanger shaft in the vertical direction, whereby a second end portion of the heat exchanger shaft is coupled to the automated lifting device.

In another embodiment, a crucible is positioned in an interior portion of a furnace chamber which includes a bottom wall and side walls that define the interior portion. The crucible is configured to contain a crystalline material growth process. A heat exchanger with an elongated shaft that extends in a vertical direction is positioned such that the shaft traverses the bottom wall of the furnace chamber. A first end portion of the heat exchanger shaft is coupled to the crucible, and a second end portion of the heat exchanger shaft is coupled to an automated lifting device. Then, a load at the crucible on the heat exchanger shaft is determined. In response to the determined load at the crucible, the automated lifting device is actuated to adjust a position of the heat exchanger shaft in the vertical direction.

### BRIEF DESCRIPTION OF THE DRAWINGS

The foregoing and other objects, features, aspects and advantages of the embodiments disclosed herein will become more apparent from the following detailed description when taken in conjunction with the following accompanying drawings.

FIG. 1 illustrates a conventional crystalline material growth system.

FIG. 2 illustrates a diagrammatic side view of a crystalline material growth system with an exemplary automated heat exchanger alignment means.

FIG. 3 illustrates a partial, cross-sectional side view of the seal design of the crystalline material growth system with the exemplary automated heat exchanger alignment means.

FIG. 4 illustrates a diagrammatic side view of active forces in the crystalline material growth system with the exemplary automated heat exchanger alignment means.

FIG. 5 illustrates an exemplary procedure for automated heat exchanger alignment in a crystalline material growth system.

It should be understood that the above-referenced drawings are not necessarily to scale, presenting a somewhat simplified representation of various preferred features illustrative of the basic principles of the disclosure. The specific design features of the present disclosure, including, for example, specific dimensions, orientations, locations, and shapes, will be determined in part by the particular intended application and use environment.

### DETAILED DESCRIPTION OF THE EMBODIMENTS

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

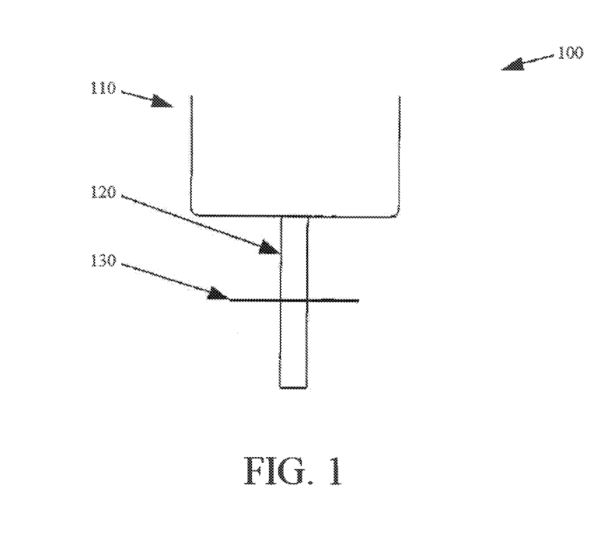

FIG. 1 illustrates a conventional crystalline material growth system. As shown in FIG. 1, a conventional crystalline material growth system 100 includes a crucible 110, a heat exchanger shaft 120, and a furnace chamber bottom wall 130.

The crucible 110 can conventionally be any container known in the art for holding, melting, and resolidifying a feedstock material. For example, when producing silicon or sapphire crystal, quartz or graphite crucibles are typical, respectively. Additionally or alternatively, the crucible 110 may be made of, for example, molybdenum, silicon carbide, silicon nitride, composites of silicon carbon or silicon nitride with silica, pyrolytic boron nitride, alumina, or zirconia and, optionally, may be coated, such as with silicon nitride, to prevent cracking of the ingot after solidification. The crucible 110 may preferably be non-rotatable and non-movable. The crucible 110 may also have a variety of different shapes having at least one side and a bottom, including, for example, cylindrical, cubic or cuboid (having a square cross-section), or tapered.

The crucible 110 may be disposed in an interior portion of a crystallization furnace including a furnace chamber having a bottom wall and side walls that define the interior portion. Illustratively, FIG. 1 depicts the bottom wall 130 of the furnace chamber. The crystallization furnace may be any device suitable for heating and melting a feedstock material at high temperatures, e.g., greater than 1000° C., and subsequently for allowing resolidification of the melted feedstock material. Suitable furnaces include, for example, crystal growth furnaces and DSS furnaces. Typically, the furnace may be provided in two parts, e.g., a furnace top and a furnace bottom, which can be separated in order to access the interior portion of the furnace, for example, to load the crucible 110 therein. The inside of the furnace may further include a crucible block in which the crucible 110 may be secured to provide added stability and rigidity. The outside of the bottom of the furnace 130 may include a base, upon which the furnace bottom sits.

The heat exchanger may include an elongated shaft 120 that extends in a vertical direction, e.g., an up-and-down direction as shown in FIG. 1, and traverses the bottom wall of the furnace chamber 130. A first end portion of the heat exchanger shaft 120 may be coupled to the crucible 110, and particularly, a base of the crucible 110. The heat exchanger may maintain a particular temperature of a melted feedstock by allowing cooling fluid to pass through the heat exchanger shaft 120.

In a typical HEM implementation, feedstock material, e.g., silicon or aluminum oxide, may be placed at the bottom of the crucible 110 and then melted by heating the crucible walls. After the feedstock material is melted, it may be cooled to allow for resolidification while the heat exchanger maintains the resulting crystal at a temperature slightly below its melting point, e.g., using cooling fluid passing through the heat exchanger shaft 120. Soon thereafter, crystallization initiates and the resolidified material expands in three dimensions. When crystallization is complete, the furnace temperature is decreased and the crystal ingot slowly anneals. The crystallization process in its entirety may take approximately 72 hours.

Notably, in conventional crystalline material growth systems, such as crystalline material growth system 100, the heat exchanger shaft 120 cannot be moved after it is installed. In other words, the heat exchanger shaft 120 is fixed in a particular position. However, as explained above, because the load at the crucible 110 varies according to a number of factors, the fixed heat exchanger shaft 120 causes a constantly changing clamp force between the crucible 110 and the heat exchanger. Therefore, the overall efficiency, stability, and predictability of the crystalline material growth system may be negatively affected. Moreover, in conventional crystalline material growth systems, such as crystalline material growth system 100, the crucible 110 is loaded into the furnace chamber at room temperature and shimmed in-place in order to position the crucible 110 inside the furnace. Using such a loading technique may hinder the ability to properly and efficiently position the crucible 110 in the furnace chamber on a recurring basis. The disclosed embodiments are intended to address at least the aforementioned drawbacks in conventional crystalline material growth systems.

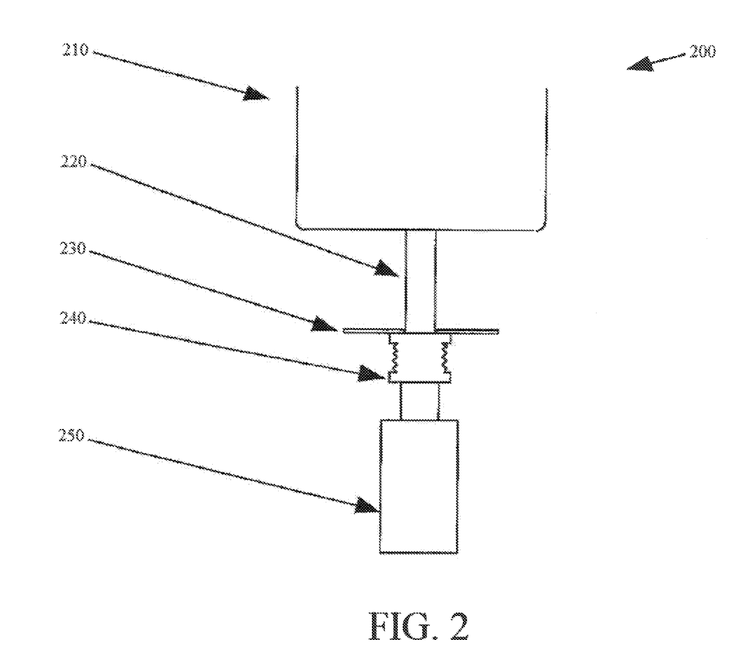

FIG. 2 illustrates a diagrammatic side view of a crystalline material growth system with an exemplary automated heat exchanger alignment means. As shown in FIG. 2, a crystalline material growth system 200 includes a crucible 210, a heat exchanger shaft 220, a furnace chamber bottom wall 230, a bellow 240, and an automated lifting device 250.

The crucible 210 may be any container known in the art for containing a crystalline material heating process, e.g., holding, melting, and resolidifying a feedstock material, such as the crucible 110 shown in FIG. 1. The crucible 210 may be disposed in an interior portion of a crystallization furnace including a furnace chamber. It may be preferred that the crucible 210 be positioned approximately in the center of the furnace chamber. In order to load the crucible 210 into the approximate furnace center, a flat, level centering ring (not shown) may be used. In particular, the centering ring may be placed under the crucible 210 to allow for centering and solid support of the crucible edge. Use of the centering ring may eliminate the need for shimming the crucible 210 into position in the furnace chamber.

The furnace chamber may include a bottom wall and side walls that define the interior portion, in which the crucible 210 is disposed. Illustratively, FIG. 2 depicts the bottom wall of the furnace chamber 230. The crystallization furnace may be of any suitable type, as described in detail above.

The crystalline material growth system 200 includes a heat exchanger having an elongated shaft 220 that extends in a vertical direction, e.g., an up-and-down direction as shown in FIG. 2. The heat exchanger shaft 220 may traverse the bottom wall of the furnace chamber 230, such that a first portion of the heat exchanger shaft 220 is positioned inside the furnace chamber, while a second portion of the heat exchanger shaft 220 is positioned outside the furnace chamber. A first end portion, e.g., an upper end portion as shown in FIG. 2, of the heat exchanger shaft 220 may be coupled to the crucible 210. The heat exchanger shaft 220 may be coupled to the crucible 210 via any suitable manner including, for example, being in thermal communication with the crucible and/or being in direct, physical contact with the crucible. A cap disposed at the first end portion (not shown) may be operable to engage with a bottom portion of the crucible 210. Importantly, in the crystalline material growth system 200, the position of the heat exchanger shaft 220 is adjustable, not fixed, in the vertical direction, as described in further detail below.

A flexible bellow 240 may be disposed substantially adjacent to the bottom wall of the furnace chamber 230. The bellow 240 may be configured to mount the heat exchanger shaft 220 to the bottom wall of the furnace chamber 230. Illustratively, the bellow 240 may be disposed between the furnace chamber and the automated lifting device 250, as described in further detail below. Moreover, the bellow 240 may allow for axial motion of the heat exchanger shaft 220.

In order to adjust the position of the heat exchanger shaft 220, a lockable automated lifting device 250 may be used. The automated lifting device may be any device suitable for adjusting a position of the heat exchanger shaft so as to counteract a downward force of the crucible, and for locking the heat exchanger shaft into place, including, for example, an air cylinder, a servomotor, a hydraulic lift, or the like. A second end portion, e.g., a lower end portion as shown in FIG. 2, of the heat exchanger shaft 220 may be coupled to the automated lifting device 250. As such, the automated lifting device 250 may be configured to be actuated, e.g., via a proportional valve (not shown), to adjust a position of the heat exchanger shaft 220 in the vertical direction. More specifically, the automated lifting device 250 may be configured to adjust the position of the heat exchanger shaft 220 in response to a load at the crucible 210 on the heat exchanger shaft 220. In other words, the automated lifting device 250 may be configured to adjust the position of the heat exchanger shaft 220 so as to cause a force at the heat exchanger shaft 220 that counteracts the load at the crucible 210.

It should be understood that changing the position of the heat exchanger shaft 220 also changes the force it exerts against adjacent components, namely the crucible 210. Thus, because the automated lifting device 250 may be actuated to adjust the position of the heat exchanger shaft 220, the heat exchanger shaft counterforce (against the crucible 210) is also adjustable. As explained above, the loads at the crucible 210 may vary on a run-by-run basis, due to inconsistent feedstock amounts, crucibles of differing weights, etc. Therefore, because the counterforce of the heat exchanger shaft 220 against the crucible 210 may also be varied on a run-by-run basis, in response to the current load at the crucible 210, the clamp force between the heat exchanger shaft 220 and the crucible 210 may be kept constant run after run. As a result, this allows for a repeatable interface in the crystalline material growth system, even in spite of potential dimensional changes due to thermal expansion, thereby increasing the overall efficiency, stability, and predictability of the system. Moreover, this allows for the heat exchanger to be readily field-replaceable, since the automated lifting device 250 may adjust the positioning of any suitable heat exchanger.

In addition, the automated lifting device 250 may be configured to lock the heat exchanger shaft 220 into place once the correct position and resulting counterforce of the heat exchanger shaft 220 is reached. This allows for the heat exchanger shaft 220 to be moved into the correct position after the heat exchanger shaft 220 is heated to its maximum temperature, and after the heat exchanger shaft 220 is stable in its length. This is advantageous to HEM implementations where the heat exchanger may only be moved into a desired position before the heat exchanger is heated to its maximum temperature.

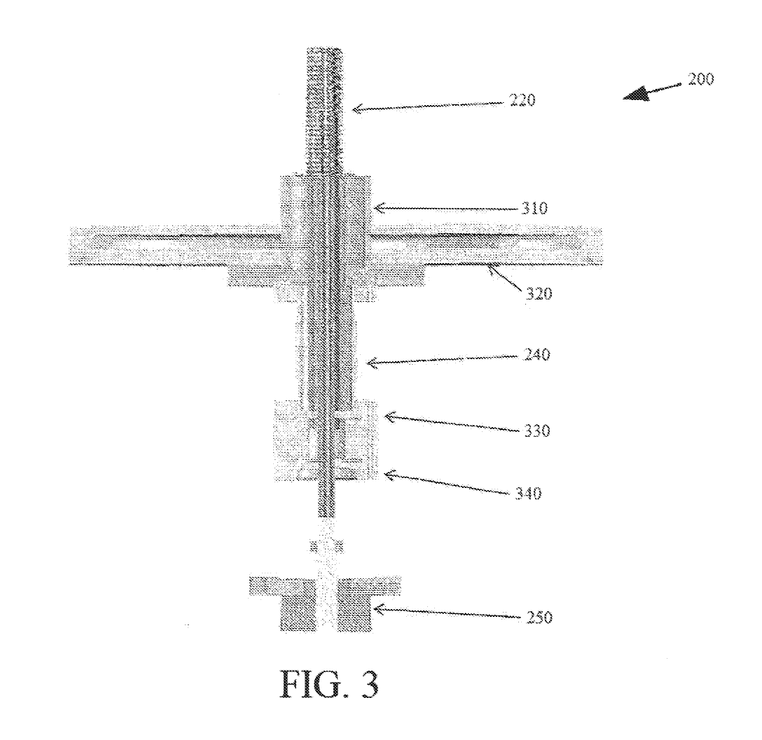

FIG. 3 illustrates a partial, cross-sectional side view of the seal design of the crystalline material growth system with the exemplary automated heat exchanger alignment means. As shown in FIG. 3, the crystalline material growth system 200 includes the heat exchanger shaft 220, the bellow 240, the automated lifting device 250, a cooling flange 310, a bottom wall flange 320, an inner tube flange 330, and an outer tube flange 340. Notably, the seal design illustrated in FIG. 3 is configured for improved leak integrity of the automated heat exchanger alignment means described herein.

A bottom wall flange 320 may be disposed in the bottom wall of the furnace chamber 230, as shown in FIG. 2. An opening may be disposed in the bottom wall flange 320. The heat exchanger shaft 220 may traverse the bottom wall of the furnace chamber 230 via the opening in the bottom wall flange 320. It should be noted that the size, e.g., diameter, of the bottom wall flange 320 is directly proportional to the clamp force between the crucible 210 and the heat exchanger shaft 220. Thus, as the clamp force between the crucible 210 and the heat exchanger shaft 220 increases, the diameter of the bottom wall flange 320 may also increase, and vice versa.

Also, a cooling flange 310 may further be disposed through the opening of the bottom wall flange 320. A bottom portion of the cooling flange 310 may be disposed substantially adjacent to an upper portion of the bellow 240. The cooling flange 310 may surround the heat exchanger shaft 220 and act as a guide to allow for vertical motion, i.e., movement in the vertical direction, of the heat exchanger shaft 220.

The heat exchanger shaft 220 may consist of a two-piece gun-drilled tip with a reusable weld assembly of a conflate flange and molybdenum tube. The heat exchanger shaft 220 may further consist of an inner tube flange 330 and an outer tube flange 340. The inner tube flange 330 and the outer tube flange 340 may be disposed along the heat exchanger shaft 220 between the furnace chamber and the automated lifting device 250.

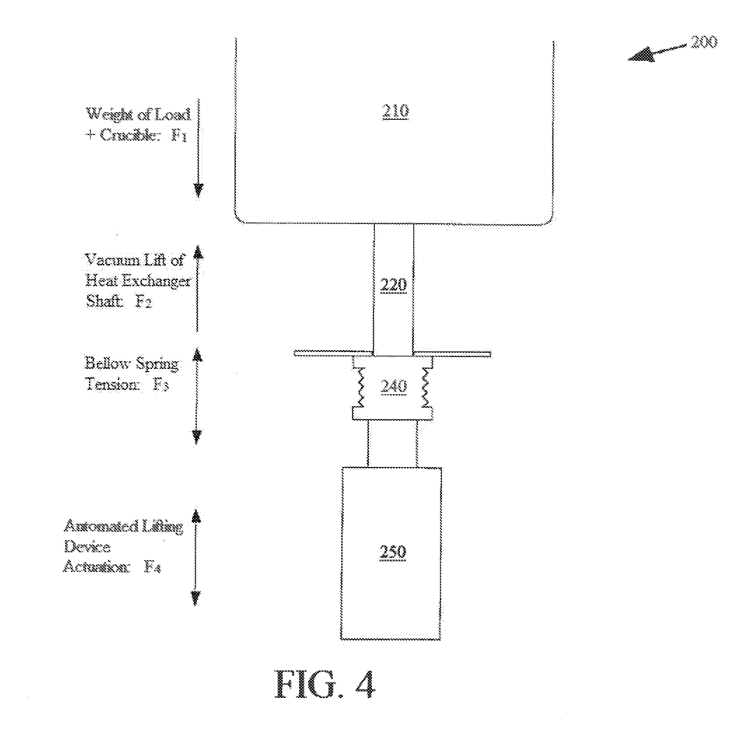

FIG. 4 illustrates a diagrammatic side view of active forces in the crystalline material growth system with the exemplary automated heat exchanger alignment means. As shown in FIG. 2, a crystalline material growth system 200 includes a crucible 210, a heat exchanger shaft 220, a bellow 240, and an automated lifting device 250, as well as designations of forces F₁-F₄ active in the automated heat exchanger alignment means described herein.

As explained above, the automated lifting device 250 may be configured to adjust the position of the heat exchanger shaft 220 in response to a load at the crucible 210 on the heat exchanger shaft 220. In other words, the automated lifting device 250 may be configured to adjust the position of the heat exchanger shaft 220 so as to cause a force at the heat exchanger shaft 220 that counteracts the load at the crucible 210. As further explained above, the load at the crucible 210 varies on a run-by-run basis, according to one or more factors. Those factors include, for example, a weight of the crucible and contents therein (e.g., F₁), a vacuum lift of the heat exchanger shaft (e.g., F₂), a spring tension of a bellow (e.g., F₃), and an actuation force of the automated lifting device (e.g., F₄).

More specifically, the load at the crucible 210 may be determined using the following formula (1):

Load at the crucible=weight of the crucible−lift force of the heat exchanger shaft (F₂)−bellow spring tension (F₃)−actuation force of the automated lifting device (F₄) (1)

Based on the above formula (1), the current load at the crucible 210 on the heat exchanger shaft 220 may be computed. It may be useful to conduct a series of experiments in conjunction with a load cell to determine the correct load at the crucible 210. Based on this result, it can be determined in which direction and at which force the automated lifting device 250 should be actuated. The actuation of the automated lifting device 250 adjusts the position of the heat exchanger 220, and thereby the lift force of the heat exchanger shaft (F₂). Accordingly, the automated heat exchanger alignment means is able to maintain the clamp force between the heat exchanger shaft 220 and the crucible 210 at a constant value run after run.

Notably, as illustrated in FIG. 4, the forces caused by the weight of the crucible and contents therein (F₁) and the vacuum lift of the heat exchanger shaft (F₂) act in opposite directions. In particular, the weight of the crucible and contents therein (F₁) exert a downward force, while the lift of the heat exchanger shaft (F₂) exerts an upward force (as shown in FIG. 4). In contrast, the forces caused by the spring tension of a bellow (F₃) and the actuation force of the automated lifting device (F₄) may act in either an upward or downward direction (as shown in FIG. 4).

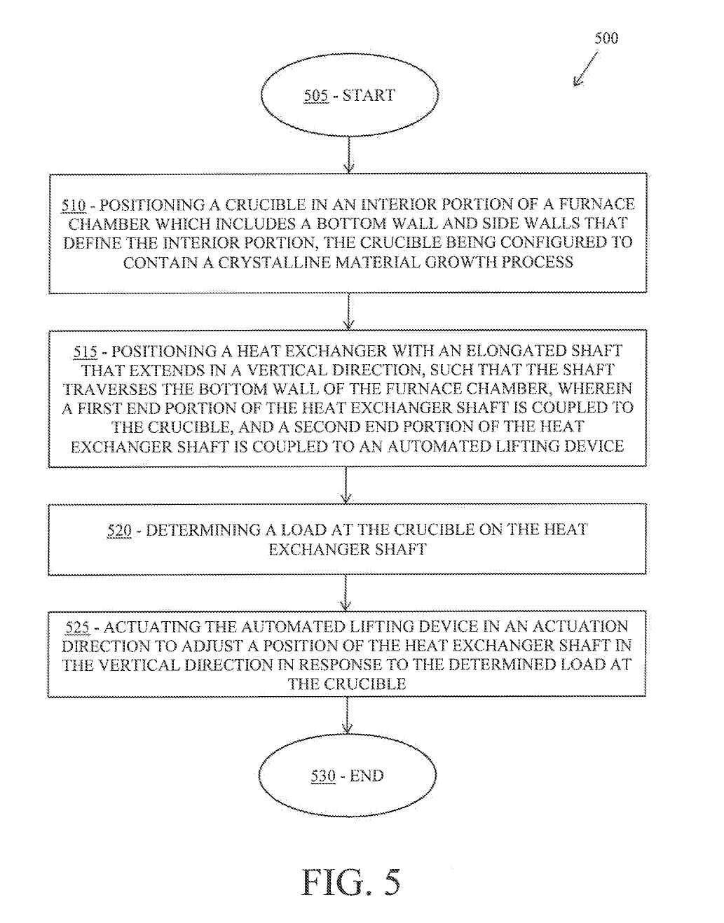

FIG. 5 illustrates an exemplary procedure for automated heat exchanger alignment in a crystalline material growth system. As shown in FIG. 5, the procedure 500 may start at step 505, continue to step 510, and so forth, where, as described in greater detail above, an automated lifting device may be configured to adjust the position of the heat exchanger shaft in response to a load at the crucible on the heat exchanger shaft.

At step 510, a crucible is positioned in an interior portion of a furnace chamber which includes a bottom wall and side walls that define the interior portion. The crucible is configured to contain a crystalline material growth process. At step 515, a heat exchanger with an elongated shaft that extends in a vertical direction is positioned such that the shaft traverses the bottom wall of the furnace chamber. A first end portion of the heat exchanger shaft is coupled to the crucible, and a second end portion of the heat exchanger shaft is coupled to an automated lifting device. Then, at step 520, a load at the crucible on the heat exchanger shaft is determined. In response to the determined load at the crucible, the automated lifting device is actuated to adjust a position of the heat exchanger shaft in the vertical direction, at step 525. The procedure 500 illustratively ends at step 530. The techniques by which the steps of procedure 500 may be performed, as well as ancillary procedures and parameters, are described in detail above.

It should be understood that the steps shown in FIG. 5 are merely examples for illustration, and certain steps may be included or excluded as desired. Further, while a particular order of the steps is shown, this ordering is merely illustrative, and any suitable arrangement of the steps may be utilized without departing from the scope of the embodiments herein.

The components, arrangements, and techniques described herein, therefore, provide for an automated apparatus and method for aligning a heat exchanger. As noted above, because the counterforce of the heat exchanger shaft against the crucible may be adjusted in response to the current load at the crucible, the clamp force between the heat exchanger shaft and the crucible may be kept constant run after run. As a result, this allows for a repeatable interface in the crystalline material growth system, even in spite of potential dimensional changes due to thermal expansion, thereby increasing the overall efficiency, stability, and predictability of the system. Furthermore, use of the centering ring may allow for centering and supporting the crucible, thus eliminating the need for shimming the crucible into position in the furnace chamber. Even further, the disclosed seal design may be configured for improved leak integrity of the automated heat exchanger alignment means.

While there have been shown and described illustrative embodiments that provide for an automated heat exchanger alignment means, it is to be understood that various other adaptations and modifications may be made within the spirit and scope of the embodiments herein, with the attainment of some or all of their advantages. Therefore, it is the object of the appended claims to cover all such variations and modifications as come within the true spirit and scope of the embodiments herein.

What is claimed is:

1. An apparatus, comprising:
a furnace chamber including a bottom wall and side walls that define an interior portion;
a crucible disposed in the interior portion of the furnace chamber and configured to contain a crystalline material growth process;
a heat exchanger including an elongated shaft that extends in a vertical direction and traverses the bottom wall of the furnace chamber, a first end portion of the heat exchanger shaft being coupled to the crucible; and
an automated lifting device configured to be actuated in an actuation direction to adjust a position of the heat exchanger shaft in the vertical direction, a second end portion of the heat exchanger shaft being coupled to the automated lifting device.

2. The apparatus according to claim 1, wherein the automated lifting device is further configured to adjust the position of the heat exchanger shaft in response to a load at the crucible on the heat exchanger shaft.

3. The apparatus according to claim 2, wherein the automated lifting device is further configured to adjust the position of the heat exchanger shaft so as to cause a force at the heat exchanger shaft that counteracts the load at the crucible.

4. The apparatus according to claim 2, wherein the load at the crucible varies according to one or more of: a weight of the crucible and contents therein, a lift force of the heat exchanger shaft, a spring tension of a bellow, and an actuation force of the automated lifting device.

5. The apparatus according to claim 1, wherein the automated lifting device is further configured to adjust the position of the heat exchanger shaft after the heat exchanger is heated to a maximum temperature.

6. The apparatus according to claim 1, wherein the automated lifting device is further configured to lock the heat exchanger shaft into place.

7. The apparatus according to claim 1, further comprising a bottom wall flange having an opening and being disposed in the bottom wall of the furnace chamber, wherein the heat exchanger shaft traverses the bottom wall of the furnace chamber via the opening in the bottom wall flange.

8. The apparatus according to claim 7, further comprising a cooling flange disposed through the opening of the bottom wall flange, wherein the cooling flange surrounds the heat exchanger shaft and allows for vertical motion of the heat exchanger shaft.

9. The apparatus according to claim 1, further comprising a flexible bellow disposed substantially adjacent to the bottom wall of the furnace chamber, wherein the bellow is configured to mount the heat exchanger shaft to the bottom wall of the furnace chamber.

10. The apparatus according to claim 9, wherein the bellow allows for axial motion of the heat exchanger shaft.

11. The apparatus according to claim 9, wherein the bellow is disposed between the furnace chamber and the automated lifting device.

12. The apparatus according to claim 1, further comprising a centering ring that positions the crucible in the interior portion of the furnace chamber.

13. The apparatus according to claim 1, wherein the heat exchanger further includes an inner tube flange and an outer tube flange, the inner tube flange and the outer tube flange being disposed between the furnace chamber and the automated lifting device.

14. The apparatus according to claim 1, wherein the automated lifting device is an air cylinder, a servomotor, or a hydraulic lift.

15. A method, comprising:
positioning a crucible in an interior portion of a furnace chamber which includes a bottom wall and side walls that define the interior portion, the crucible being configured to contain a crystalline material growth process;
positioning a heat exchanger with an elongated shaft that extends in a vertical direction, such that the shaft traverses the bottom wall of the furnace chamber, wherein a first end portion of the heat exchanger shaft is coupled to the crucible, and a second end portion of the heat exchanger shaft is coupled to an automated lifting device;
determining a load at the crucible on the heat exchanger shaft; and
actuating the automated lifting device in an actuation direction to adjust a position of the heat exchanger shaft in the vertical direction in response to the determined load at the crucible.

16. The method according to claim 15, wherein the actuating of the automated lifting device comprises causing a force at the heat exchanger shaft that counteracts the load at the crucible.

17. The method according to claim 15, further comprising heating the heat exchanger to a maximum temperature, wherein the actuating of the automated lifting device to adjust the position of the heat exchanger shaft occurs after the heat exchanger is heated to the maximum temperature.

18. The method according to claim 15, further comprising locking the heat exchanger shaft into place via the automated lifting device.

19. The method according to claim 15, wherein the determining of the load at the crucible depends on one or more of: a weight of the crucible and contents therein, a lift force of the heat exchanger shaft, a spring tension of a bellow, and an actuation force of the automated lifting device.

20. The method according to claim 15, wherein the automated lifting device is an air cylinder, a servomotor, or a hydraulic lift.
